(19) United States
(12) Patent Application Publication
(10) Pub. No.: US 2006/0019035 A1
(43) Pub. Date: Jan. 26, 2006

(54) Base for decorative layer

(75) Inventors: Wolf-Dieter Munz, Vienna (AT); Papken Ehiasar Hovsepian, Sheffield (GB)

Correspondence Address: ROSENBAUM & ASSOCIATES, P.C., 650 DUNDEE ROAD, SUITE 380, NORTHBROOK, IL, 60062-2757, US

(73) Assignee: Sheffield Hallam University

(21) Appl. No.: 11/241,638

(22) Filed: Sep. 30, 2005

(30) Foreign Application Priority Data
Mar. 31, 2003 (GB) 0307380.6
Apr. 15, 2003 (GB) 0308630.3

(51) Int. Cl. C23C 14/00

(52) U.S. Cl. 427/402; 427/523

(57) ABSTRACT

A base for a decorative layer is provided comprising a first material capable of forming an anodic oxide and a second capable of forming an interference metal oxide formed on the first material. The material capable of forming an anodic oxide layer may comprise a barrier layer formed on a substrate. A decorative layer is formed by anodic oxidation of the layer comprising a material capable of forming an interference metal oxide to form an oxide layer formed on the material capable of forming an interference metal oxide, wherein the oxide layer is configured to have a thickness suitable to cause interference of incident light.

### CROSS-REFERENCE TO RELATED APPLICATIONS

The present application claims priority to PCT International Application No. PCT/GB2004/001317, which claims priority to Great Britain Application No. 0307380.6, filed Mar. 31, 2003 and Great Britain Application No. 0308630.3, filed Apr. 15, 2003.

### FIELD OF THE INVENTION

The present invention relates to decorative layers.

### BACKGROUND TO THE INVENTION

Decorative and/or protective metal layers on metal substrates are commonly deposited using either “wet” methods, thermal spraying or commercial physical vapour deposition (herein referred to as PVD).

Wet methods are used to deposit metals such as platinum, nickel and chromium. However, these layers provide a limited range of colours as there are no techniques currently available that allow these layers to develop primary colours. The wet method of electroplating tends to deposit thick layers that can obscure fine features on objects to be coated.

PVD coating techniques are commercially used primarily to deposit wear resistant layers onto implements such as cutting tools and also to deposit hard wearing gold covered titanium nitride layers for decorative purposes.

Several metals are capable of being subjected to anodic oxidation (sometimes referred to as anodizing) to form hard surface layers. Anodic oxidation is an electrochemical conversion process that converts the outer surface of the metal to its associated oxide. This is achieved by making the part that is to be anodically oxidized the anode of an electrical circuit within an electrolyte. The electrolyte is typically acidic, and when an electrical field is applied to the circuit, an oxide layer is formed on the outer surface on the metal. Properties of the oxide layer, such as porosity, can be controlled by controlling the anodizing conditions. For example, low acid concentration and low anodizing temperature will give a less porous and harder layer. Higher anodizing temperatures will lead to a more porous, softer layer.

Certain metal oxides are capable of displaying the valve effect. This is where electrical conductivity of the oxide is unilateral; that is, current can flow across a valve metal oxide in one direction only, thereby making them conductors in one direction and insulators in another. Oxides of aluminum, titanium, niobium and tantalum all display the valve effect.

Certain metal oxides, including those of niobium, tantalum and certain compositions of titanium/aluminium alloys, at a certain thickness will cause interference with incident light. This effect can be used to give coatings a particular colour. The observed colour is dependent upon the thickness of the layer. The colour does not have a narrow bandwidth, but comprises a range of wavelengths in the visible spectrum over a relatively broad bandwidth. However, the bandwidth does not extend across the visible spectrum, and so the surface of the metal oxide will have a colour. This colour is referred to herein as a specific colour.

The specific colour observed is also dependent upon the refractive index of the metal oxide. Metal oxides that have a refractive index suitable to cause interference with incident light are herein referred to as interference metal oxides. Examples of interference metal oxides are oxides of niobium, tantalum and titanium/aluminium alloys.

FIG. 1A illustrates the prior art interference effect. A niobium layer 101 is deposited on a substrate 102 and anodized to form a niobium oxide (Nb₂O₅) surface layer 103. When incident light 104 strikes the surface layer 103, a first portion of the light 105 is reflected from the oxide layer 103, and a second portion of the light 106 is refracted through the oxide layer 103. The refracted light 106 is reflected from the niobium layer 101 to give a third portion of light 107. The reflected third portion of light 107 is also refracted as it exits the niobium oxide surface 103 to give a fourth portion of light. It is known that light travels in waves and waves may interact by interference. Interference between the first portion of light 105 and the fourth portion of light 108 can cause the surface layer 103 to appear to be a specific colour to a user 109.

The colour that a user 109 sees is dependent upon the angle from which the user 109 views the layer 103. This is illustrated in prior art FIG. 1B, wherein incident light 110 is reflected 111, and also refracted 112 in the same way as in the example above. The refracted light 112 is reflected from the niobium layer 101, and the reflected light 113 is refracted as it exist the niobium oxide surface layer 103. The interference between the light 111, 114 as seen by the user 109 again makes the surface layer appear to be a specific colour to the user 109. However, as the distance between the light 111, 114 seen by the user 109 is different, the interference effect makes the surface 103 appear to be a different colour.

A problem with layers that provide colour by interference of light is that the colour seen by the user 109 can vary widely depending upon the angle at which the user 109 perceives the layer 103. It is desirable to minimize this directional colour effect.

Niobium oxide, tantalum oxide and certain titanium/aluminium alloys (in particular around 50 atomic % titanium/50 atomic % aluminium) oxide surfaces give rise to interference colours. These can be deposited by a reactive PVD process, wherein niobium, tantalum or an alloy of titanium/aluminium is evaporated in an atmosphere of oxygen and argon and deposited on the surface. This process is expensive, and requires a lot of process control. In particular, there are difficulties in getting a uniform thickness of layer on a three-dimensional object because it is a line-of-sight process, and so the thickness of the oxide surface in a recess of the surface may be less than the thickness of the oxide surface on larger flat surfaces. As mentioned above, the specific colour of the coated object is dependent upon the thickness of the oxide layer, and so it is difficult to obtain coated objects of a uniform specific colour using the reactive PVD process.

A simpler process is to deposit tantalum, niobium or an alloy of titanium/aluminium layers directly by PVD, and then subjecting this layer to anodic oxidation to form an oxide layer that gives interference colours.

In practice, it is very difficult to deposit niobium, tantalum or titanium/aluminium alloy layers without porosity appearing within those layers. The presence of porosity can either prevent the anodization of the surface layer to form an oxide, or introduce variations in the thickness of the oxide layer, thereby leading to variations in the colour of the surface. FIG. 2 illustrates this problem, wherein the niobium layer 201 on an iron substrate 202 contains a pore 206. When the niobium layer is subjected to anodic oxidation, the electrolyte (not shown) can enter the pore 201, and the pore can act as a current sink 207 down to the substrate 202. If the current sink is sufficiently large, anodic oxidation of the niobium layer 201 is prevented, thereby preventing formation of a niobium oxide layer.

Pores 203 in the niobium layer 201 may not be of a suitable size to reduce the current over the surface of the niobium oxide layer to a negligible amount. However, the electric field around the pores will be reduced locally, which will give rise to a region of a different thickness of the niobium oxide layer during anodic oxidation. This will reduce the thickness of the anodic oxide layer, and therefore alter the specific colour of the layer produced by interference of light. To a person viewing the surface, this will be apparent as localised regions of different colour to the rest of the surface. These imperfections in the otherwise uniform colour of the surface layer are not desirable. Furthermore, if the porosity is sufficiently uniform and widespread, the thickness of the surface oxide layer may be lower than that required to give a certain colour, and so whilst surface may have a uniform colour it may not be the colour originally desired.

A simple solution to prevent the problems associated with porosity is to deposit a thick metal layer, and to subsequently anodize the layers to form a thick oxide layer. However, this process is time consuming and expensive.

### SUMMARY OF THE INVENTION

The inventors have realised the problems associated with non-uniform thickness in oxide layers for decorative surfaces and the problems with porosity in layers that are anodized to form oxide layers, and have devised a layer and a method of producing the layer that greatly improves the tolerances of the thickness, thereby producing uniform reproducible colours on a layer.

The inventors have devised a means for reducing the problems associated with pores by depositing a barrier layer on the substrate prior to depositing the layer comprising a material capable of forming an interference metal oxide. The barrier layer can be deposited to a greater thickness than the layer comprising a material capable of forming an interference metal oxide, and as the barrier layer is also capable of forming an anodic oxide layer that acts as a valve material, current sinks do not form around pores in the layer comprising a material capable of forming an interference metal oxide.

Furthermore, the inventors have devised a layer that suppresses the directional colour effect.

According to a first aspect of the present invention, there is provided a method of forming a base for a decorative layer, said method comprising:

forming a material capable of forming an interference metal oxide onto a material capable of forming an anodic oxide.

Preferably, the material capable of forming an interference metal oxide is formed using a PVD process.

Preferably, the material capable of forming an anodic oxide layer comprises;

a barrier layer;

wherein the barrier layer is formed on a substrate.

Preferably, the barrier layer is formed using a PVD process.

Preferably, the barrier layer has a thickness in the range of 0.2 to 5 μm.

According to a second aspect of the invention, there is provided a base for a decorative layer, the base comprising:

a first material capable of forming an anodic oxide; and

a second material capable of forming an interference metal oxide formed on the first material.

Preferably, the material capable of forming an interference metal oxide is formed using a PVD process.

Preferably, the material capable of forming an anodic oxide layer comprises; a barrier layer;

wherein the barrier layer is formed on a substrate.

Preferably, the barrier layer is formed using a PVD process.

According to a third aspect of the present invention, there is provided apparatus for forming a base for a decorative layer, the base for a decorative layer comprising:

a first material capable of forming an anodic oxide; and

a second material capable of forming an interference metal oxide formed on the first material;

the apparatus comprising PVD equipment.

Preferably, the PVD equipment comprises:

multiple targets; and

means to selectively expose the multiple targets; and

unbalanced magnetron sputtering configured for depositing said first material and said second material.

According to a fourth aspect of the present invention, there is provided a decorative layer comprising:

a barrier layer formed on a substrate, the barrier layer configured to form an oxide layer in response to anodizing in an electrolyte; and

a layer comprising a material capable of forming an interference metal oxide formed on the barrier layer; and

an oxide layer formed on the layer comprising a material capable of forming an interference metal oxide.

### BRIEF DESCRIPTION OF THE DRAWINGS

For a better understanding of the invention and to show how the same may be carried into effect, there will now be described by way of example only, specific embodiments, methods and processes according to the present invention with reference to the accompanying drawings in which:

FIG. 1 illustrates schematically the prior art interference effect of oxide layers with incident light.

FIG. 2 illustrates schematically the prior art problem in anodizing a surface layer where pores exists in the surface layer.

FIG. 3 illustrates schematically a layer comprising a material capable of forming an interference metal oxide deposited on a substrate capable of forming an anodic oxide.

FIG. 4 illustrates schematically apparatus for depositing a layer comprising a material capable of forming an interference metal oxide and/or a barrier layer.

FIG. 5 illustrates schematically the growth of an anodic oxide layer.

FIG. 6 shows the thickness of an anodic oxide layer as a function of anodizing time for different metals and alloys.

FIG. 7 illustrates schematically the effect of deposition temperature on the crystal structure of the deposited layer.

FIG. 8 illustrates schematically a layer comprising a material capable of forming an interference metal oxide formed directly on a substrate capable of forming an anodic oxide layer.

FIG. 9 illustrates schematically a surface layer on a polymer substrate.

FIG. 10 illustrates schematically the effect of surface roughness on the interference colour of the layer comprising an interference metal oxide.

FIG. 11 illustrates schematically a barrier layer comprising multiple sublayers.

FIG. 12 shows the colours produced by different anodic oxide layers comprising different materials at different voltages.

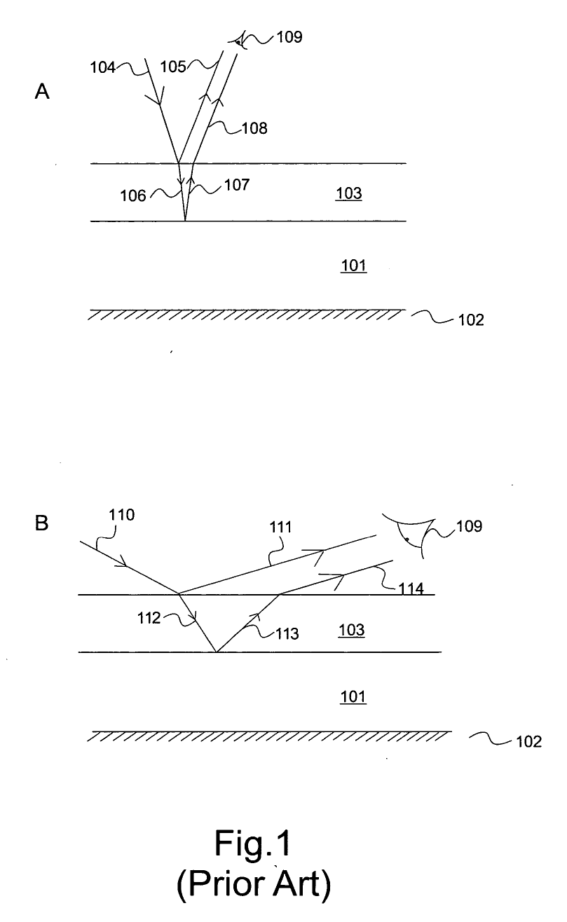

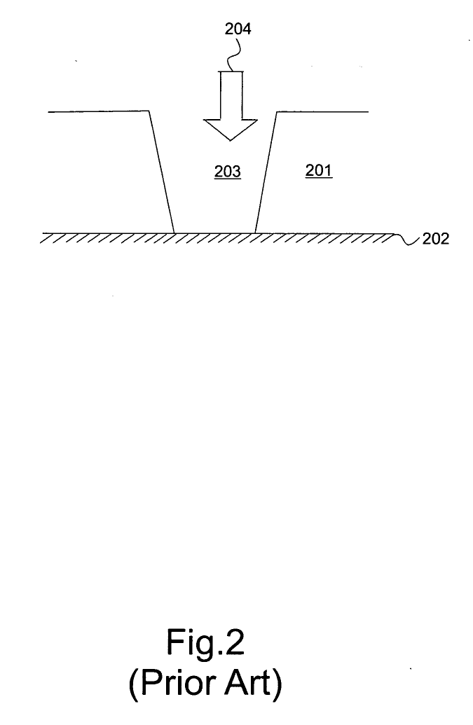

### DETAILED DESCRIPTION OF A SPECIFIC MODE FOR CARRYING OUT THE INVENTION

There will now be described by way of example a specific mode contemplated by the inventors. In the following description numerous specific details are set forth in order to provide a thorough understanding. It will be apparent however, to one skilled in the art, that the present invention may be practiced without limitation to these specific details. In other instances, well known methods and structures have not been described in detail so as not to unnecessarily obscure the description.

References to an interference metal oxide herein refer to a metal oxide with a refractive index suitable to cause interference with visible light. Examples of such interference metal oxides include oxides of niobium, tantalum and titanium/aluminium alloys.

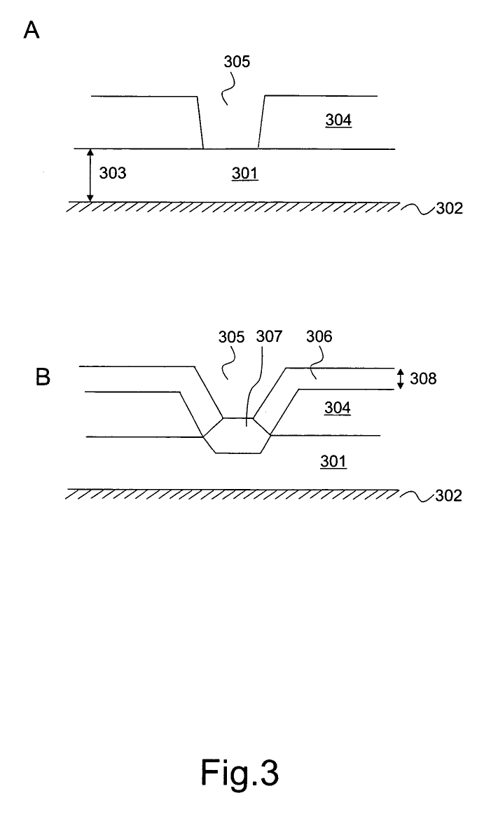

Referring to FIG. 3 herein, there is illustrated a layer of a material capable of forming an interference metal oxide deposited on a substrate capable of forming an anodic oxide layer. There is illustrated a barrier layer 301 having a thickness 303, a substrate 302, and a layer comprising a material capable of forming an interference metal oxide 304 in which a pore 305 is formed. This arrangement is used as a base for a decorative layer.

The barrier layer 301 is deposited by means of PVD onto a substrate 302 to be coated. The substrate 302 comprises any suitable material, for example iron or steel. The barrier layer 301 comprises any material capable of forming an anodic oxide, or any material capable of forming an anodic oxide that exhibits the valve effect. This includes, but is not limited to, any one of aluminum, titanium, niobium or tantalum, or alloys of aluminum, titanium, niobium or tantalum. The thickness 303 is sufficient to ensure that there is minimal open porosity between the barrier layer 301 and the material 302 to be coated. A thickness in the range of 0.2 to 5 μm has been found to be suitable.

Where the barrier layer 301 comprises aluminium or titanium, it is formed in the PVD process by sputtering an aluminium or titanium target respectively. Where the barrier layer 301 is an alloy of aluminum, the barrier layer 301 is formed by co-sputtering of an aluminum target and other alloy material target, including targets of tantalum or niobium. Where the barrier layer comprises an alloy of titanium, it is produced by sputtering a titanium alloy target.

A layer comprising a material capable of forming an interference metal oxide 304 is then deposited by PVD onto the barrier layer 301. A pore 305 is also shown extending through the layer comprising a material capable of forming an interference metal oxide 304 to the barrier layer 301.

Referring to FIG. 3B herein, there is illustrated an anodic oxide layer 306 formed on layer comprising a material capable of forming an interference metal oxide 304, and an anodic oxide layer 307 formed on the barrier layer 301.

Anodic oxidation takes place in an electrolyte, as is well known. An anodic oxide layer 306 forms on the surface of the layer comprising a material capable of forming an interference metal oxide 304. However, the electrolyte enters the pore 305 and without the presence of a barrier layer 301 would form a current sink at the substrate 302. However, with the barrier layer 301 present, anodic oxidation of the barrier layer 301 takes place to form an oxide layer 307 within the pore 305. As the oxide of the barrier layer 301 is a valve material, a current sink cannot form because the oxide of the barrier layer allows conduction in only one direction. There is therefore no drop in current density around the pore 305, and so no localized variations in thickness of the anodic oxide layer 306 around the pore 305.

PVD layers have columnar structure, and voids between the columns can connect the electrolytes directly to the substrate 302, thereby forming a current sink. Interruption of the columnar growth can be achieved by using a plurality of layers. In this instance, the plurality of layers comprises layers comprising a material capable of forming an interference metal oxide deposited on a barrier layer. When forming the layer comprising a material capable of forming an interference metal oxide, growth occurs by re-nucleation on the surface of the barrier layer 301, thereby interrupting columnar growth. The overall density of the layer comprising a material capable of forming an interference metal oxide and the barrier layer therefore increases, because continuation of pores 305 from the barrier layer 301 to the layer comprising a material capable of forming an interference metal oxide 304 is less likely.

By using a barrier layer 301, that does not give rise to interference colours, the problems associated with porosity in anodic oxide layer 306 can be avoided.

PVD Apparatus

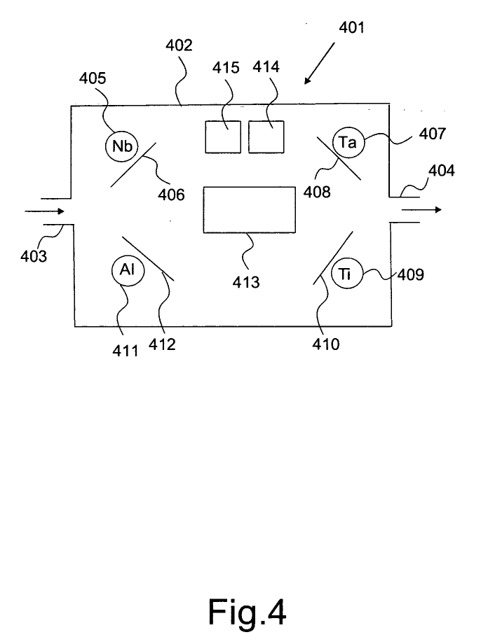

Referring to FIG. 4, there is illustrated schematically apparatus for depositing a layer comprising a material capable of forming an interference metal oxide and/or a barrier layer. The apparatus comprises PVD equipment 401 comprising a chamber 402, an inlet for gas 403, an outlet 404 configured to allow a vacuum to form in the chamber 402, multiple targets comprising materials for depositing 405, 407, 409, 411, shields 406, 408, 410, 412 to selectively expose the targets, a substrate 413 to be coated with a layer and at least one energy source 414.

In a first mode of operation, known as evaporation, the substrate 413 is placed within the chamber 402 under vacuum. A target 405 is heated by the energy source 414 to a point where it starts to evaporate, and exposed to the substrate 413 by opening a shield 406. Evaporated molecules condense on the substrate 413 thereby forming a layer on the substrate.

Evaporation may be achieved by several methods, including thermal evaporation and arc evaporation. In the thermal evaporation process, a target 403 is heated using the energy of an electron beam or other thermal source. On the other hand, arc evaporation utilizes an electric arc discharge, concentrated in a few μm² area (known as a “cathode spot”) on the surface of the target 405. The temperature in the cathode spot can reach 6000° C. which results in evaporation of the material. The vapour produced is highly ionized (up to 90%). Where arc evaporation is used, a target 405 is connected to a specialised power supply.

In a second mode of operation, known as sputtering, an inert gas such as argon is introduced at low pressure via an inlet 403 into the chamber 402. An argon plasma is struck using the energy source 414, which typically comprises a radio frequency power source or unbalanced magnetron power source. A target 405 is exposed using a shield 406 and argon plasma ions are accelerated towards the target 405. This causes atoms of the source material to break off from the target 405 and condense on all surfaces including the substrate 413.

With electrically conductive substrates, most PVD processes utilize ion plating. Ion plating is a process which requires a negative potential of typically minus 75V to be applied to the substrate 413 during the coating process. The advantage of ion plating is the production of layers of a higher density. An additional power supply 415 is connected to the substrate 413 to negatively bias the substrate 413 during the PVD deposition of a layer. The bias voltage may be varied between −50V to −350V depending on the substrate material.

In a third mode of operation, known as the reactive PVD process, a gas such as oxygen or nitrogen is introduced via an inlet 403 with an inert gas such as argon during the evaporation process. This causes an oxide or nitride layer to be deposited on the substrate 413.

Formation of Anodic Oxide Layer

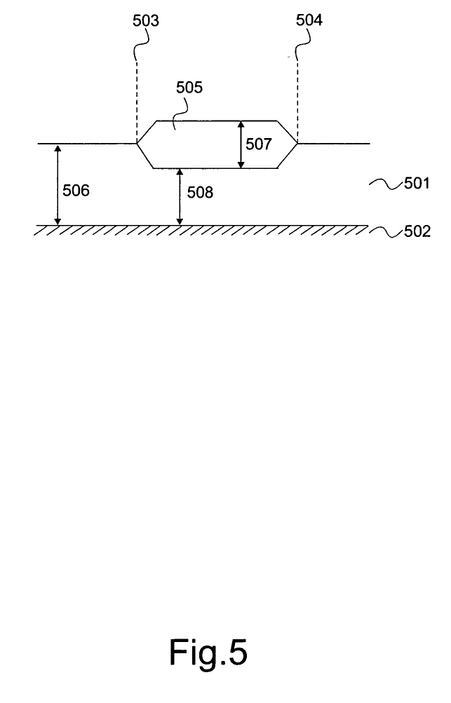

Referring to FIG. 5 herein, there is illustrated the formation of an anodic oxide layer. The layer capable of forming an anodic oxide layer 501 is deposited upon a material to be coated 502, and is anodically oxidized over a certain area 503, 504. An anodic oxide layer 505 develops on the surface of the layer 501. The resistivities of the layer 501 and the anodic oxide layer 505 are material properties, and so the resistance of the surface layer is governed by the thickness 506 of the layer 501 and the thickness 507 of the anodic oxide layer 505.

As the formation voltage reaches its limit, defined by the capabilities of the power supply, the current density J_{F} reduces because the thickness of anodic oxide layer increases and the resistance of the anodic oxide layer increases accordingly. As J_{F} approaches 0, and the voltage is constant, a very precise indication of the thickness 507 of the anodic oxide layer 505 can be obtained because no more growth of the anodic oxide layer occurs. This allows for very precise prediction of the thickness of the anodic oxide layer, which can be used to accurately define the specific colour of the surface layer. For example, for tantalum anodized in a field of 100 V the thickness of the tantalum oxide layer is 160 nm±0.16 nm.

As an example. where the layer is tantalum (Ta), the formation voltage (U_{F}) is around 6×10⁶V/cm. The formation voltage, current and resistance are related by Ohm's Law. At a constant current, a linear increase of U^{F} will lead to a linear increase in the thickness of the tantalum oxide layer 505. The thickness of the tantalum oxide layer 505 increases by 1.6 nm/V, whereas the thickness 508 of the tantalum layer 501 below the tantalum oxide layer 505 decreases by around 0.6 nm/V. The density of tantalum is around 16 g/cm³, whereas the density of the tantalum oxide layer is around 8 g/cm³, and therefore the combined thickness of the tantalum layer 501 and the tantalum oxide layer 505 increases as the thickness 507 of the tantalum oxide layer 505 increases.

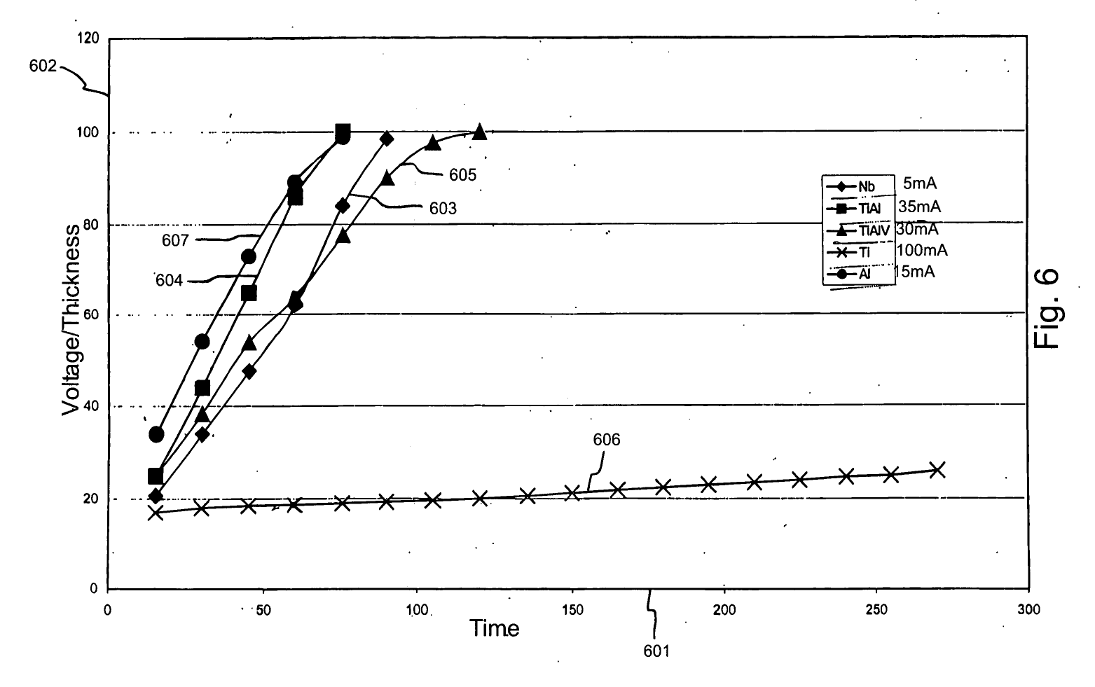

Referring to FIG. 6 herein, there is shown the thickness of an anodic oxide layer as a function of anodizing time for different metals and alloys. The x-axis 501 represents time, and the y-axis represents either voltage or anodic oxide layer thickness. The different curves illustrated represent the increase in thickness as a function of time for niobium 503, a titanium aluminum alloy 505, a titanium aluminum vanadium alloy 505, titanium 506 and aluminum 507.

It is apparent from FIG. 6 that where pure titanium is used to form a barrier layer, high current density is required to grow a layer of an appreciable thickness, and so relatively long periods of time are required to form an anodic oxide layer. It has been found that where a titanium based sputtering target is used during the PVD process to form the barrier layer, the presence of between 5 and 55 atomic percent aluminum gives rise to a barrier layer that can be anodically oxidized to form an anodic oxide form layer more efficiently. A titanium alloy that improves the speed of formation of anodic oxide layer is 90 weight percent titanium, 6 weight percent aluminum and 4 weight percent vanadium.

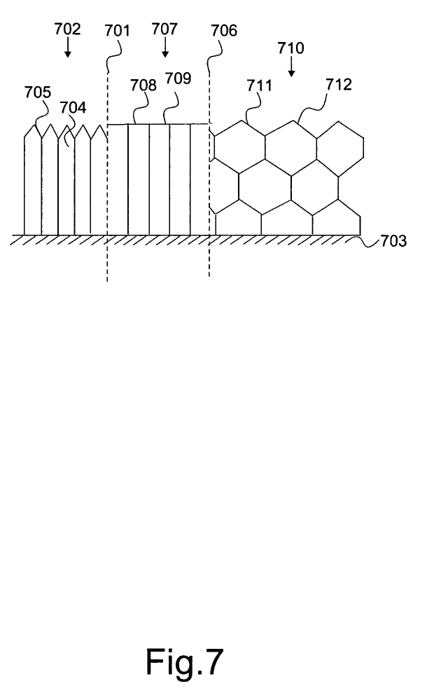

Referring to FIG. 7 herein, the effect of deposition temperature of the crystal structure of the deposited layer is schematically illustrated. This can apply to deposition of the barrier layer or deposition of the layer capable of forming an interference metal oxide. Where the deposition temperature is up to one third of the melting temperature of the deposited metal or metal alloy 701, the crystal structure of the deposited layer 702 on the substrate 703 is open columnar. This structure is characterized by having needle-like grains 704 and regions of porosity 605. In addition to surface porosity, there is also porosity between the grains 704 Where the deposition temperature is between one third 701 and two thirds 706 of the melting temperature of the metal, a crystal structure is dense columnar 607. This provides for a dense layer 708 with a smooth surface 709.

Where the deposition temperature is above two thirds 706 of the melting temperature, the crystal structure of the deposited layer is equiaxed 710. This provides for a uniform crystal structure of equiaxed grains 711 with some surface roughness 712.

According to a second specific embodiment of the present invention, there is provided a surface layer deposited directly onto a substrate capable of forming an anodic oxide layer. In this embodiment, there is no need for a barrier layer as the surface to be coated is already capable of forming an anodic oxide layer, and therefore any porosity in the deposited layer will not act as a current sink.

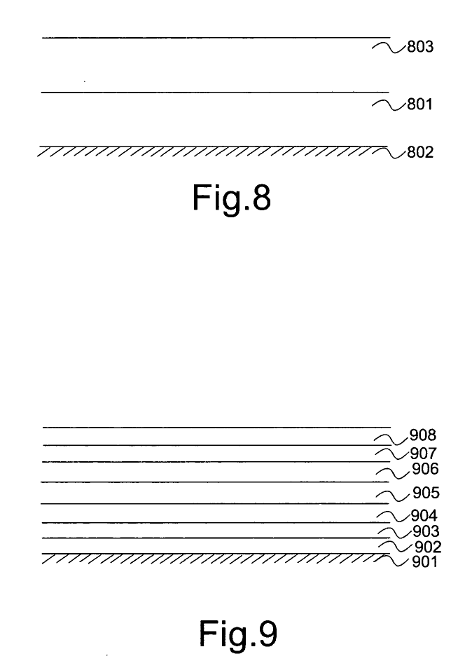

Referring to FIG. 8 herein, there is illustrated schematically a surface layer formed directly on a substrate capable of forming an anodic oxide layer. The surface layer 801 comprising a material capable of forming an interference metal oxide is deposited by PVD directly on a substrate 802 capable of forming an anodic oxide layer. The layer comprising a material capable of forming an interference metal oxide can then be anodized to form anodic oxide layer 803 on the surface of the layer comprising a material capable of forming an interference metal oxide 801.

In a third specific embodiment of the invention, a layer comprising a material capable of forming an interference metal oxide and a barrier layer is coated onto a polymer substrate, provided that the alloy chosen for the barrier layer can be deposited at temperatures sufficiently low to avoid damage to the polymer substrate. The polymer substrate is electroplated with a metal to protect the polymer substrate and give better adhesion with the barrier layer

Referring to FIG. 9 herein, there is illustrated a surface layer on a polymer substrate. The polymer substrate 901 is electroplated with a layer of copper 902, a layer of nickel 903 and a layer of chrome 904. These electroplated layers provide some protection for the polymer substrate 901 during the deposition of the barrier layer and the layer comprising a material capable of forming an interference metal oxide, and also provide better adhesion to the barrier layer.

A barrier layer 905 which is capable of forming an anodic oxide is deposited by the PVD process. A layer comprising a material capable of forming an interference metal oxide 906 is then deposited by a PVD process onto the barrier layer 905. The layer comprising a material capable of forming an interference metal oxide is then anodically oxidized to form a hard colour-stable anodic oxide layer 907 on the surface of the layer comprising a material capable of forming an interference metal oxide 906.

A further layer 908 may also be deposited to prevent wear of the anodic oxide layer, and therefore protect the coated object. This protective layer 908 comprises any suitable material with sufficient hardness and a low refractive index, for example silica. This protective layer can be used in conjunction with any specific embodiment described herein.

As discussed herein, the colour of the anodic oxide layer depend upon the angle from which it is viewed. In a fourth specific embodiment of the invention, this directional colour appearance of the anodic oxide layer is suppressed, thereby making the surface layer appear to be the same colour regardless of the angle from which it is viewed.

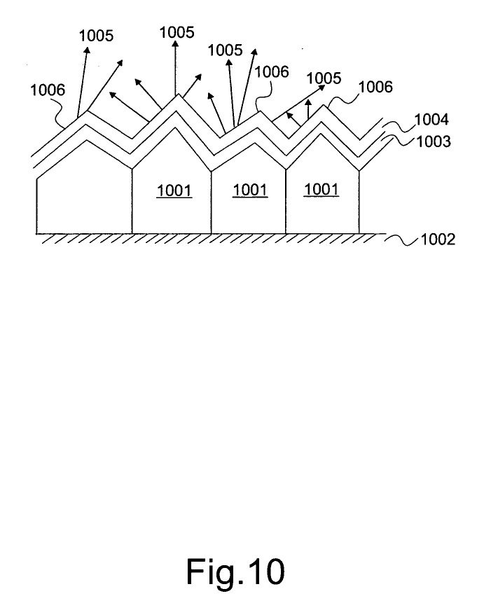

Referring to FIG. 10 herein, there is illustrated schematically a cutaway view of the fourth specific embodiment. A barrier layer 1001 comprising equiaxed grains is shown deposited on a substrate 1002. A layer comprising a material capable of forming an interference metal oxide 904 is deposited on the barrier layer 1001 using the PVD process, and then anodically oxidized to form an anodic oxide layer 1004. If the surface roughness is suitably dimensioned, then the refracted light will be scattered in many different directions, and on average the same number of surface facets 1006 will be visible to a viewer regardless of the direction from which the surface layer is viewed. In this way, the surface of the anodic oxide layer will appear to be the same colour regardless of the angle from which it is viewed.

Where aluminum or aluminum alloys are used as the barrier layer, it has been found that a deposition temperature of above 200° C. stimulates a grain size of the barrier layer of greater than 200 nm, thereby forming a layer with a surface roughness of greater than 100 nm. These dimensions are suitable to suppress the directional colour appearance of the anodic oxide layer.

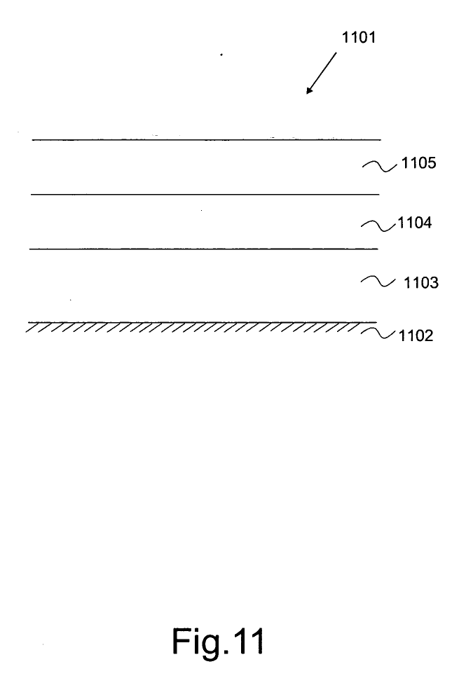

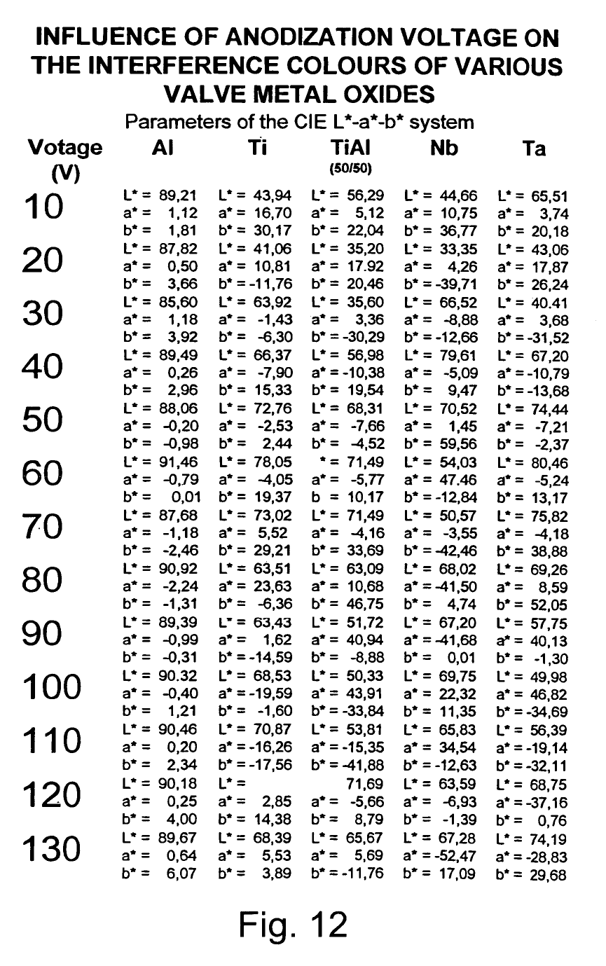

According to a fifth specific embodiment of the invention, the barrier layer comprises sub-layers that have been deposited successively to form a multi-layer. Referring to FIG. 11 herein, there is illustrated schematically a barrier layer comprising multiple layers. The barrier layer 1101 is deposited on a substrate 1002, and comprises at least a first sub-layer 1103, a second sub-layer 1104, and optionally further sub-layers 1105. These sub-layers are deposited successively by a PVD process.

An advantage of a multi-layer barrier layer 1101 is that it minimizes any problems associated with porosity in individual layers, and also minimizes any problems associated with low temperature deposition of the metal, for example the formation of an open columnar crystal structure 702.

It has been found that an ideal thickness for the sublayers is 1 nm to 5 nm.

A multi-layer barrier layer 1101 may comprise thousands of sublayers to build up a multi-layer barrier layer 1101 with a thickness of around 1μm to 3μm. These nanoscale multi-layers (also known as superlattice structures) provide a more reliable barrier layer against penetration of the electrolyte to the substrate compared to decorative layers comprising only one layer comprising a material capable of forming an interference metal oxide and one barrier layer, owing to the decreased in porosity of the barrier layer, thereby minimizing the chance of forming a current sink during anodic oxidation.

A further problem associated with depositing thick barrier layers by a PVD process is that the rapid changes in temperature can lead to very high thermal stresses. These thermal stresses can lead to lamination of the barrier layer or the layer comprising a material capable of forming an interference metal oxide, thereby preventing adhesion between the layers or between the layers and the substrate.

The problem of high stresses leading to lamination is overcome by depositing a soft first sub-layer with a Vickers Hardness of between 400 and 1000, and a thickness of greater than 5 nm. Subsequent sub-layers have a thickness of between 1 nm to 5 nm and are significantly harder, with a Vickers Hardness of greater than 2000. The addition of a soft sub-layer 1003 adjacent to the substrate 1002 allows for some degree of flexibility in the multi-layer, and thereby minimizes the problems associated with lamination.

As an additional stage to any one of the embodiments described herein, the substrate is subjected to ion implantation using an ion implantation material prior to forming a barrier layer or a layer comprising a material capable of forming an interference metal oxide onto a substrate. The use of an ion implantation material aids adhesion between the substrate and a layer coated on the substrate. Furthermore, ion implantation reduces porosity and defects in a layer coated on the substrate.

The ion implantation material may comprise any suitable material. Examples of suitable materials are niobium, tantalum, titanium and titanium alloys.

As an additional stage to any one of the embodiments described herein, the barrier layer is either partially or fully deposited using the PVD process in a reactive atmosphere. Suitable atmospheres include a mixture of argon and oxygen, a mixture of argon and nitrogen, or a mixture of argon, nitrogen and oxygen. Where the layers are deposited in a partial oxygen atmosphere, oxide layers are formed directly.

As an additional stage to any of the embodiments described herein, the deposition of the barrier layer and the layer comprising a material capable of forming an interference metal oxide is carried out using multi-target PVD equipment using a cathodic arc as an evaporation source and unbalanced magnetrons for sputtering. The advantage of this type of equipment is that different targets can be exposed at different times, to build up multiple layers of different materials in one process.

Tantalum or niobium is used in this process as ion implantation material, to improve adhesion between the substrate and the barrier layer.

Alternatively, the ion implantation process can be performed utilizing droplet-free high power impulse magnetic sputtering (HIPIMS) using either tantalum or niobium or titanium or a titanium alloy as target material prior to the deposition of the barrier layer. This material acts as an ion implantation material, which improves the adhesion between the barrier layer and the substrate, and reduces the number of defects in the barrier layer.

Anodic Oxidation Techniques

The following techniques of anodic oxidation apply to any one of the previous embodiments described herein. Once the layer comprising a material capable of forming an interference metal oxide has been deposited on to a barrier layer or a substrate, the layer comprising a material capable of forming an interference metal oxide is then anodized to form an oxide layer. Anodic oxidation of the layer comprising a material capable of forming an interference metal oxide can be performed in an aqueous solution of citric acid at an electrolyte temperature of 20° C. to 90° C. It has also been found that the addition of ammonium citrate reduces resistivity, thereby reducing the voltage drops over three dimensional surface features and increasing the uniformity of the anodic oxide layer thickness. It is therefore easier to control the colour of the finished surface after anodic oxidation.

It has been found that optimum conductivity and resistivity during anodic oxidation can be achieved using a solution of ammonium pentaborate in glycol at an electrolyte temperature of between 20° C. and 90° C.

### EXAMPLE

To further illustrate the range of colours that can be achieved using anodic oxide layers, FIG. 12 shows the colours produced by different anodic oxide layers comprising different materials at different voltages. The colours are defined by means of the CIE L*a*b* system. These are for layers of aluminium, titanium, niobium, tantalum and a titanium/aluminum alloy. The surface layers have been anodized using electric fields ranging from ten volts to 130 volts.

Whilst the CIE L*a*b* system accurately describes the colours of the layers, to further illustrate the colours that can be obtained, when a niobium layer is anodized using an electric field ranging from 10 volts to 90 volts, the observed interference colour of the surface ranges from gold to purple to blue to light grey to silver to yellow to pink to purple to turquoise to green.

1. A method of forming a base for a decorative layer, said method comprising the step of forming a material capable of forming an interference metal oxide onto a material capable of forming an anodic oxide.

2. A method of forming a base for a decorative layer as claimed in claim 1 wherein said material capable of forming an anodic oxide layer comprises;
a barrier layer;
wherein said barrier layer is formed on a substrate.

3. A method of forming a base for a decorative layer as claimed in claim 2 wherein said barrier layer has a thickness in the range of about 0.2 to 5 μm.

4. A method of forming a base for a decorative layer as claimed in claim 2 wherein said barrier layer comprises aluminium or an alloy of aluminium.

5. A method of forming a base for a decorative layer as claimed in claim 2 wherein said barrier layer comprises titanium or an alloy of titanium.

6. A method of forming a base for a decorative layer as claimed in claim 5 wherein said titanium alloy comprises aluminium in the range of about 5 to 55 atomic %.

7. A method of forming a base for a decorative layer as claimed in claim 5 wherein said titanium alloy comprises:
about 90 weight % titanium; and
about 6 weight % aluminium; and
about 4 weight % vanadium.

8. A method of forming a base for a decorative layer as claimed in claim 2 wherein said barrier layer comprises at least two sublayers.

9. A method of forming a base for a decorative layer as claimed in claim 8 wherein each said sublayer has a thickness in the range of about 1 nm to 5 nm.

10. A method of forming a base for a decorative layer as claimed in claim 8 wherein said barrier layer comprises:
a first sublayer formed on said substrate, said first sublayer having a thickness greater than 5 nm and a Vickers Hardness in the range of about 400 to 1000; and
at least a second sublayer, said second sublayer having a Vickers Hardness greater than about 2000;
wherein said barrier layer is resistant to lamination in response to stress.

11. A method of forming a base for a decorative layer as claimed in claim 4 comprising:
depositing said barrier layer at a temperature greater than 200° C.;
wherein said barrier layer comprises equiaxed grains with an average grain size greater than 200 nm; and
said barrier layer has a surface roughness greater than 100 nm;

12. A method of forming a base for a decorative layer as claimed in claim 2 comprising:
ion implantation of said substrate with an ion implantation material prior to forming said barrier layer on said substrate, said ion implantation material selected from the group consisting of niobium; tantalum; titanium; and titanium alloy.

13. A method of forming a base for a decorative layer as claimed in claim 12 comprising ion implantation by PVD cathodic arc evaporation.

14. A method of forming a base for a decorative layer as claimed in claim 12 comprising ion implantation utilising droplet-free HIPIMS.

15. A method of forming a base for a decorative layer as claimed in claim 2 comprising:
forming said barrier layer by a reactive PVD process in an atmosphere selected from the group consisting of argon and oxygen, argon and nitrogen, and argon, oxygen and nitrogen.

16. A method of forming a base for a decorative layer as claimed in claim 2 comprising:
forming said barrier layer using a PVD unbalanced magnetron sputtering technique.

17. A method of forming a base for a decorative layer as claimed in claim 2 comprising:
forming said barrier layer using a PVD process, said PVD process comprising at least one of multiple target sources, cathodic arc evaporation or unbalanced magnetron sputtering.

18. A method for forming a base for a decorative layer as claimed in claim 1 comprising the steps of:
anodizing said material capable of forming an interference metal oxide in an electrolyte;
whereby an oxide layer is formed on a surface of said material capable of forming an interference metal oxide; and
said oxide layer is configured to have a thickness suitable to cause interference of incident light.

19. A method of forming a base for a decorative layer as claimed in claim 18 wherein said electrolyte comprises any of:
aqueous citric acid at a temperature in a range of 20° C. to 90° C.
aqueous citric acid and ammonium citrate at a temperature in a range of 20° C. to 90° C.
ammonium pentaborate in glycol at a temperature in a range of 20° C. to 90° C.

20. A method of forming a base for a decorative layer as claimed in claim 18 comprising the stepsof:
forming a protective layer on said oxide layer, said protective layer comprising a material with a low refractive index.

21. A method of forming a decorative layer as claimed in claim 18 comprising the steps of:
forming at least one metal layer at a polymer surface; and
forming a barrier layer on said metal layer; and
forming a layer comprising a material capable of forming an interference metal oxide on said barrier layer; and
anodizing said layer comprising a material capable of forming an interference metal oxide to form an oxide layer; and
forming a protective layer on said oxide layer.

22. A base for a decorative layer, said base comprising:
a first material capable of forming an anodic oxide; and
a second material capable of forming an interference metal oxide formed on said first material.

23. A base for a decorative layer as claimed in claim 22 wherein said material capable of forming an anodic oxide layer comprises;
a barrier layer;
wherein said barrier layer is formed on a substrate.

24. A base for a decorative layer as claimed in claim 23 wherein said barrier layer has a thickness in the range of 0.2 to 5 μm.

25. A base for a decorative layer as claimed in claim 23 wherein said barrier layer comprises aluminium or an alloy of aluminium.

26. A base for a decorative layer as claimed in claims 23 wherein said barrier layer comprises titanium or an alloy of titanium.

27. A base for a decorative layer as claimed in claim 26 wherein said titanium alloy comprises aluminium in the range of 5 to 55 atomic %.

28. A base for a decorative layer as claimed in claim 26 wherein said titanium alloy comprises:
about 90 weight % titanium; and
about 6 weight % aluminium; and
about 4 weight % vanadium.

29. A base for a decorative layer as claimed in claim 23 wherein said barrier layer comprises at least two sublayers.

30. A base for a decorative layer as claimed in claim 29 wherein each said sublayer has a thickness in the range of 1 nm to 5 nm.

31. A base for a decorative layer as claimed in claim 29 wherein said barrier layer comprises:
a first sublayer formed on said substrate, said first sublayer having a thickness greater than 5 nm and a Vickers Hardness in the range of 400 to 1000; and
at least a second sublayer, said second sublayer having a Vickers Hardness greater than 2000;
wherein said barrier layer is resistant to lamination in response to stress.

32. A base for a decorative layer as claimed in claim 25 wherein said barrier layer is formed at a temperature greater than 200° C.;
whereby said barrier layer comprises equiaxed grains with an average grain size greater than 200 nm; and
said barrier layer has a surface roughness greater than 100 nm;

33. A base for a decorative layer as claimed in claim 23 wherein said substrate is ion implanted with an ion implantation material prior to forming said barrier layer on said substrate, said ion implantation material selected from from the group consisting of niobium; tantalum; titanium; and titanium alloy.

34. A decorative layer comprising a base for a decorative layer as claimed claim 22; and
an oxide layer formed on a surface of said material capable of forming an interference metal oxide;
wherein said oxide layer has a thickness suitable to cause interference of incident light.

35. A decorative layer as claimed in claim 34 comprising a protective layer formed on said oxide layer, said protective layer having a low refractive index.

36. A decorative layer as claimed in claim 34 comprising:
at least one metal layer formed on a polymer surface; and
a barrier layer formed on said layer of metal; and
a layer comprising a material capable of forming an interference metal oxide formed on said barrier layer; and
an oxide layer formed on said layer comprising a material capable of forming an interference metal oxide; and
a protective layer on said oxide layer.
